(19) United States
(12) Patent Application Publication
(10) Pub. No.: US 2006/0228876 A1
(43) Pub. Date: Oct. 12, 2006

(54) Method of manufacturing a semiconductor device

(75) Inventors: Olaf Storbeck, Dresden (DE); Jens Hahn, Dresden (DE); Sven Schmidbauer, Dresden (DE); Juergen Faul, Radebeul (DE); Frank Jakubowski, Dresden (DE); Thomas Schuster, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 11/101,639

(22) Filed: Apr. 8, 2005

(51) Int. Cl. H01L 29/00

(52) U.S. Cl. 438/530

(57) ABSTRACT

The invention relates to a method of manufacturing a semiconductor device, in which a substrate is provided, a dielectric layer is formed on top of the substrate, an amorphous semiconductor layer id deposited on top of the dielectric layer, the amorphous semiconductor layer is doped, and a high temperature step to the amorphous layer is applied to form a crystallized layer out of the amorphous semiconductor.

### TECHNICAL FIELD OF THE INVENTION

The present invention relates to a method of manufacturing a semiconductor device and a semiconductor device fabricated by this method.

### BACKGROUND OF THE INVENTION

Although the invention can in principle be applied to any desired integrated circuit, the invention and its underlying problem will hereinafter be explained with reference to gate stacks.

Active semiconductor structures having field effect transistors are widely used in circuits. Necessary gate structures are commonly provided with a vertical gate stack over a gate channel in a substrate 51, as depicted in FIG. 3. The gate stack comprises in the following order an isolating layer 52 forming a gate dielectric; a highly doped semiconductor layer 53 used for applying the electric field through the gate dielectric upon the underlying gate channel in the substrate 1; intermediate layers 54, 55 used to prevent diffusion and providing a good adhesive interface for a highly conductive tungsten layer 56 applied on top. A structure described above is disclosed e.g. in US 2005026407.

Shrinking dimensions of the gate structures lead to higher current densities in the metallic wires 56. The semiconductor layer 53 is highly doped with appropriate materials in order to minimize the thickness of the gate depletion layer formed at the interface to the gate dielectric under application of certain potentials at the gate stack. Doping of the semiconductor layer 3 is achieved by means of ion implantation. As a doping profile can be controlled significantly better in an amorphous than in a polycrystalline semiconductor the semiconductor is deposited and doped in amorphous phase.

Semiconductor devices using the above gate stack disadvantageously have a high leakage current from the gate stack into the substrate.

### SUMMARY OF THE INVENTION

The present invention is to provide a method of manufacturing a semiconductor device, and to provide a semiconductor device having at least one gate stack comprising of a gate dielectric layer and a doped semiconductor layer manufactured in a way that provides low or at least moderate gate leakage currents.

The invention comprises, in one embodiment, providing a substrate; forming a dielectric layer on top of the substrate; depositing an amorphous semiconductor layer on top of the dielectric layer; doping the amorphous semiconductor layer; and applying a high temperature to form a crystallized layer out of said amorphous semiconductor layer.

In another embodiment, the invention comprises at least one gate stack being placed on top of a substrate and comprising a dielectric layer being in contact with the substrate and further comprising a crystalline doped semiconductor layer arranged on the dielectric layer.

The present invention is based on the fact that thermal mechanical stress due to the large thermal expansion coefficient of the amorphous semiconductor indirectly causes permanent damages in the gate stack degrading the properties of the dielectric gate layer. The inventive method uses a high temperature step crystallizing the semiconductor layer.

According to a preferred embodiment, the method comprises: depositing one or more intermediate layer with materials chosen out of one of the following materials titan, titan nitride, tungsten nitride, other metal nitrides or tungsten silicide on top of the crystalline semiconductor layer; and depositing a metal layer on top of the intermediate layer.

According to a another preferred embodiment, depositing an amorphous semiconductor layer includes the substeps: depositing a polycrystalline semiconductor having a polycrystalline phase; and changing the polycrystalline phase of the polycrystalline semiconductor to the amorphous phase by means of ion implanting of heavy ions. Alternatively, the amorphous semiconductor layer might be deposited directly in the amorphous phase.

According to a preferred embodiment the high temperature is applied for at least five seconds, more preferably for fifteen to sixty seconds.

According to a preferred embodiment the high temperature is in the range for 600° C. to 1100° C., more preferably 800° C. to 900° C. As both an application duration and the temperature control the crystallization lower or higher temperatures and longer or shorter application durations, respectively, may be applied.

According to a preferred embodiment the crystalline doped semiconductor is a polycrystalline doped semiconductor.

### BRIEF DESCRIPTION OF THE DRAWINGS

Exemplary embodiments of the invention are illustrated in the drawings and explained in more detail in the following description.

Brief description of the drawings:

FIG. 1 illustrates a partial cross-section of a gate stack according to an embodiment of the present invention.

FIGS. 2a-2e illustrate an embodiment of the present invention.

FIG. 3 illustrates a commonly known gate stack.

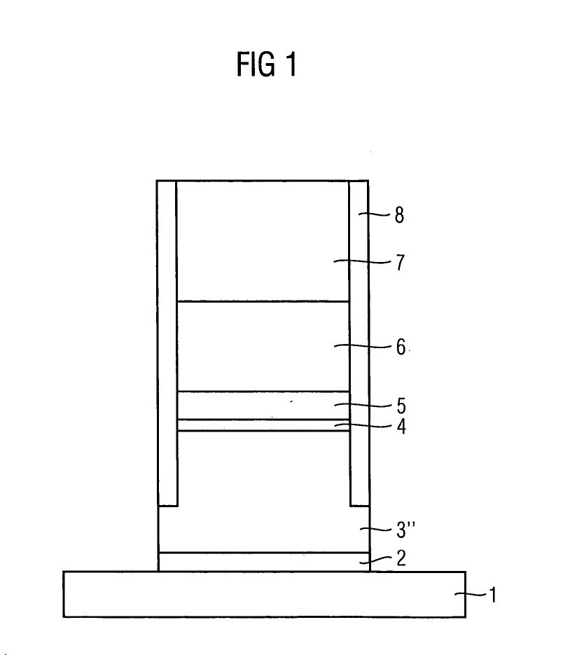

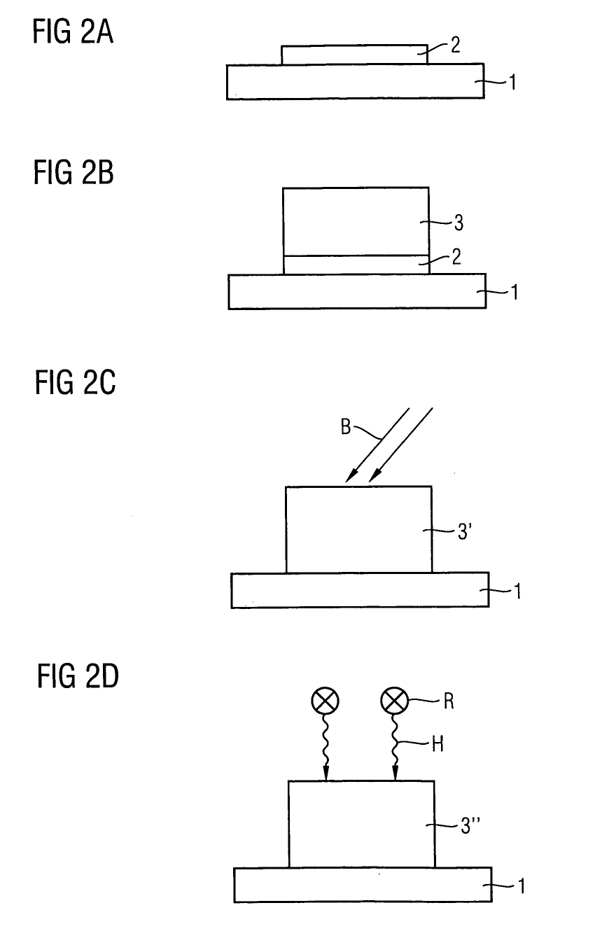

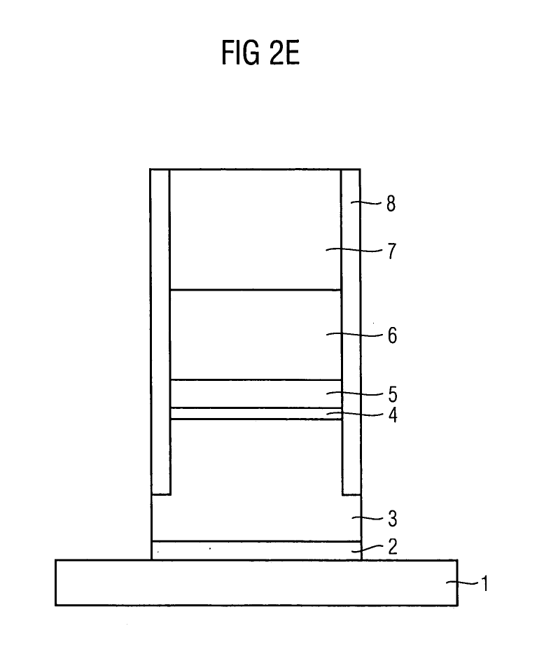

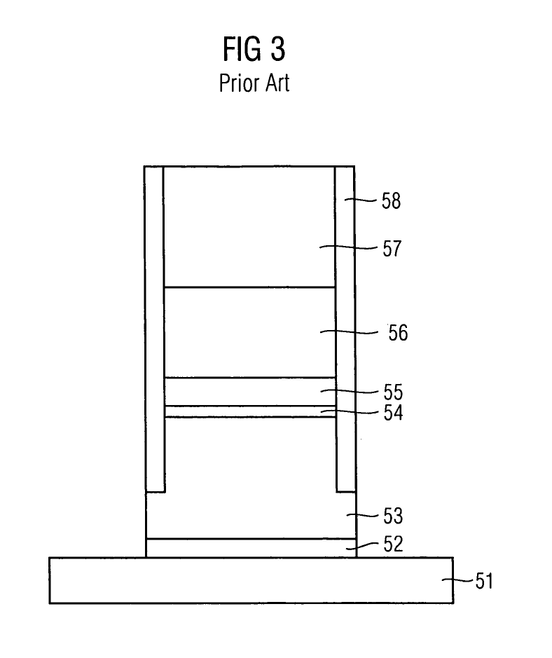

In the FIGS. 1 and 2 identical reference numerals denote identical or functionally equivalent parts.

### DETAILED DESCRIPTION OF THE INVENTION

FIG. 1 illustrates a partial cross-section of a gate stack. On a substrate 1 a vertical gate stack is placed with layers in the following order starting with the one closest to the substrate 1: a gate dielectric layer 2, a doped polycrystalline semiconductor layer 3″, some intermediate layers 4, 5, a metallic layer 6 forming a contact or wire, and finally a cap nitride 7. Nitride or oxide spacers 8 may be vertically arranged at the sides of the stack along all layers except the gate dielectric layer 2.

The substrate 1 contains typical semiconductor structures, including drain and source areas (not depicted in FIG. 1) arranged in various fashions. Commonly the substrate 1 is positively (p-type) or negatively (n-type) doped.

Above a gate area placed between a drain and a source area, a dielectric layer 2 is provided on the substrate. This dielectric layer 2 forms the gate dielectric isolating the substrate 1 from conducting structures and wires formed by the polycrystalline semiconductor layer 3 and the metallic layers 6. The resistance of the gate dielectric should be as high as possible in order to avoid leakage currents from the wires into the substrate.

The gate dielectric 2 is made very thin such that electric fields due to currents in the wires or potentials applied to the wires may reduce or increase a conductivity in the gate area. Typically the gate dielectric layer 2 has a thickness of less than 10 nm. A minimal thickness is given by the constraint that a minimal resistance of the gate dielectric layer has to be attained. Materials with a high permittivity like silicon oxide allow both a small thickness and an acceptable resistance.

The thin dielectric gate layers 2 are assumed to be very sensitive to mechanical stress. Fractures in the layer 2 or tensions in the mostly amorphous materials reduce their effective permittivity and resistance causing higher leakage currents.

As mentioned above the conductivity of the gate area is controlled by electric fields in the wires 6. Low potentials in the wires 6 with respect to the substrate 1 are preferred for several reasons. Therefore, it becomes necessary to provide the electrical fields by a semiconductor having properties similar to the properties of the substrate 1, in particular the energy levels of valence and conduction band should be nearly identical. Accordingly, a silicon layer 3 is used along with a silicon based substrate 1.

Due to a high integration density lateral structure sizes of wires and contacts are reduced. In order to minimize ohmic drops in the wirings highly conductive metal layers are deposited on the doped polycrystalline semiconductor layer 3. Further, the polycrystalline semiconductor layer 3 is highly doped such that the resistance of the gate stack is reduced. A preferred doping agent for a silicon layer 3 is boron.

Along with the FIGS. 2a-2e an embodiment forming the above semiconductor structure will be explained hereinafter.

FIG. 2a illustrates a substrate 1 provided with at least one dielectric gate layer. On top of the dielectric layer 2 a semiconductor 3 e.g. silicon is deposited and structured providing the structure illustrated in FIG. 2b. The semiconductor 3 is deposited in an amorphous phase for reasons explained herein below.

It was mentioned hereinabove that the semiconductor structure should be highly doped. The doping of the semiconductor layer 3 is done preferably by ion implantation. This method provides very good results for mono-crystalline or amorphous layers. The average implantation depth and distribution of the ions in the layer can be readily adjusted via the average velocity of the ions. The ions are stopped in the layer due to collisions with lattice atoms.

In poly-crystalline layers, however, it was demonstrated that the ions may migrate along the grain boundaries with no or less collisions then in the crystalline grains or bulk material. Thus, the ions respectively doping agents may penetrate far deeper into the layer or in worst case passing through the layer and contaminating the dielectric layer 2 or the underlying substrate 1 in the gate area. These contaminations cause a degradation of electrical characteristics of a semiconductor device e.g. leakage current, turn-off resistance of the gate channel, etc. Additionally, the level of doping agents in the polycrystalline layer would be non-uniform. For these reasons a doping of a polycrystalline layer 3 by ion implantation is not advisable.

Therefore, the semiconductor layer 3 is deposited in an amorphous state such that the doping can be achieved via ion implantation B as depicted in FIG. 2c. In case the semiconductor layer 3 is initially deposited in an polycrystalline state the semiconductor layer 3 is made amorphous e.g. by implantation of heavy ions such as germanium ions, prior doping. Thus, a doped amorphous semiconductor layer 3′ is obtained, as illustrated in FIG. 2c.

In a following processing step the doped amorphous semiconductor layer 3′ is treated at high temperature H, applied e.g. by radiators R. This high temperature is maintained for at least five seconds, preferably in the range from fifteen to sixty seconds prior the deposition of the thin intermediate layers 4, 5. The temperature is in the range of 600-1100° C., preferably within the range of 800-900° C. The purpose of this process step is to crystallize the doped amorphous semiconductor layer 3′ such that a doped polycrystalline semiconductor layer 3″ is obtained, see FIG. 2d. Above temperatures of 600° C. amorphous semiconductor materials, especially silicon, spontaneously start to crystallize.

On top of the semiconductor layer 31′ thin layers of titan, titan nitride 4 and/or tungsten nitride 5 are deposited with a thickness of less than 10 nm. The purpose of these intermediate layers 4, 5 is to prevent a diffusion of metal atoms or oxygen during the fabrication of the semiconductor device into the semiconductor layer 3″. Additionally, reactions of the semiconductor 31″ with the metal is prevented, for example silicon would react with tungsten forming a tungsten silicide layer having an uncontrolled thickness. Further, in general a metal layer 6 is not adhesive to the semiconductor material. This is especially the case for tungsten and copper on silicon. The intermediate layers 4, 5 are forming an adhesive and conductive interface between the semiconductor material and the metal layer 6. In further standard process steps a metal layer 6, a nitride cap 7 and spacer 8 are provided to the gate stack, see FIG. 2e.

The necessity of the crystallizing of the semiconductor layer shall be explained in detail herein afterwards. The gate structure, e.g. the one depicted in FIG. 2e, is exposed to several high temperature steps during the semiconductor processing of the whole device. As described above, at temperatures equal or higher than 600° C. any amorphous semiconductor 3′ will spontaneously form a polycrystalline phase. This recrystalization leads to a change in density of the semiconductor 3′ and thereby the volume occupied by the semiconductor layer 3. The volume change causes mechanical stress in the neighbouring layers, i.e. the dielectric gate layer 2 and the covering thin intermediate layers 4, 5. The neighbouring layers 2, 4, 5 may crack because of this stress.

Experiments showed that the thin intermediate layers 4, 5 are braking up such that the semiconductor layer 3′ is in direct contact to the metallic layer 6. During the high temperature steps the metal reacts with the semiconductor, especially in case of silicon and tungsten, forming metal silicides. These silicides are assumed to be cause of permanent mechanical stress within the amorphous semiconductor layer 3′. This mechanical stress at the upper surface of the amorphous semiconductor layer 3′ affects surprisingly the dielectric gate layer 2 at the lower surface through the whole semiconductor layer 3 and hence reduces the quality of the device by distorting the dielectric gate layer 2.

Once recrystallized to a polycrystalline phase the semiconductor layer 3″ exhibits no or only low volume change during subsequent thermal processing steps. Thus the neighbouring layers will suffer less mechanical stress in following high temperature steps. Therefore, the properties of the gate stack can be improved by crystallizing the amorphous semiconductor layer 3′ to a polycrystalline semiconductor layer 3″. Then the gate dielectric layer 2 performs as desired and a leakage current is at a low or moderate level.

The principle idea is to use first an amorphous semiconductor for doping and transform the amorphous semiconductor in a polycrystalline state in order to avoid thermo-mechanical stress.

Although the present invention has been described above on the basis of preferred exemplary embodiments, it is not restricted to this embodiment, but can rather be modified in numerous ways.

In particular, the semiconductor layer and intermediate layer materials can be varied in numerous ways.

What is claimed is:

1. A method of manufacturing a semiconductor device, comprising:
providing a substrate;
forming a dielectric layer on top of the substrate;
depositing an amorphous semiconductor layer on top of the dielectric layer;
doping the amorphous semiconductor layer; and
applying a high temperature step to the amorphous layer to form a crystallized semiconductor layer out of the amorphous semiconductor layer.

2. The method according to claim 1, further comprising:
depositing one or more intermediate layer with materials chosen out of one of the following materials titan, titan nitride, tungsten nitride, other metal nitrides or tungsten silicide on top of the crystalline semiconductor layer; and
depositing a metal layer on top of the intermediate layer.

3. The method according to claim 1, wherein the depositing an amorphous semiconductor layer includes:
depositing a polycrystalline semiconductor having a polycrystalline phase; and
changing the polycrystalline phase of the polycrystalline semiconductor to the amorphous phase by means of ion implanting of heavy ions.

4. The method according to claim 1, wherein during applying, the high temperature is applied for at least five seconds.

5. The method according to claim 1, wherein during the applying, the temperature is in the range for 600° C. to 1100° C.

6. A semiconductor device, comprising at least one gate stack, being placed on top of a substrate and comprising a dielectric layer being in contact with the substrate and further comprising a crystalline doped semiconductor layer arranged on top of the dielectric layer.

7. The semiconductor according to claim 6, wherein the crystalline doped semiconductor is a polycrystalline doped semiconductor.
